(19) United States
(12) Patent Application Publication
(10) Pub. No.: US 2025/0308857 A1
(43) Pub. Date: Oct. 2, 2025

(54) PLASMA GENERATION AND UV DIODE CONFIGURATIONS FOR PROCESSING CHAMBERS, AND RELATED APPARATUS AND METHODS

(71) Applicant: Applied Materials, Inc., Santa Clara, CA (US)

(72) Inventors: Khokan C. PAUL, Cupertino, CA (US); Saurabh CHOPRA, Santa Clara, CA (US)

(21) Appl. No.: 19/068,723

(22) Filed: Mar. 3, 2025

Related U.S. Application Data
(60) Provisional application No. 63/570,605, filed on Mar. 27, 2024.

(51) Int. Cl. H01J 37/32; H01L 21/02

(52) U.S. Cl. CPC H01J 37/32522; H01J 37/3244; H01J 37/32082; H01J 2237/334; H01L 21/02104

(57) ABSTRACT

The present disclosure relates to plasma generation and light-emitting diode (LED) configurations for processing chambers, and related apparatus and methods, for semiconductor manufacturing. In one or more embodiments, a processing chamber applicable for use in semiconductor manufacturing includes a chamber body at least partially defining a processing volume, and a plasma source operable to flow a plasma to the processing volume. The processing chamber includes a substrate support disposed in the processing volume, and one or more light-emitting diodes (LEDs) operable to heat the processing volume.

### CROSS-REFERENCE TO RELATED APPLICATION

This application claims the benefit of U.S. provisional patent application Ser. No. 63/570,605, filed Mar. 27, 2024, which is herein incorporated by reference in its entirety.

### BACKGROUND

### Field

The present disclosure relates to plasma generation and light-emitting diode (LED) configurations for processing chambers, and related apparatus and methods, for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposits films of various materials on a surface of a substrate in a processing chamber. During processing, various parameters can affect the uniformity of material deposited on the substrate.

However, operations (such as epitaxial deposition operations) can be long, expensive, and inefficient, and can have limited capacity and throughput. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration. The activation of gases can be limited, for example, at relatively low processing temperatures for device production (such as complementary field-effect transistor (CFET) devices). Moreover, relatively higher processing temperatures can involve unintended dopant diffusion and/or hindered device performance.

Therefore, a need exists for improved apparatuses and methods in semiconductor processing.

### SUMMARY

The present disclosure relates to plasma generation and light-emitting diode (LED) configurations for processing chambers, and related apparatus and methods, for semiconductor manufacturing.

In one or more embodiments, a processing chamber applicable for use in semiconductor manufacturing includes a chamber body at least partially defining a processing volume, and a plasma source operable to flow a plasma to the processing volume. The processing chamber includes a substrate support disposed in the processing volume, and one or more light-emitting diodes (LEDs) operable to heat the processing volume.

In one or more embodiments, a processing chamber applicable for use in semiconductor manufacturing includes a chamber body that includes an inject section and an exhaust section. The chamber body at least partially defines a processing volume. The processing chamber includes a substrate support disposed in the processing volume, and one or more light-emitting diodes (LEDs) operable to emit ultraviolet (UV) light heat the processing volume.

In one or more embodiments, a method of substrate processing includes heating a substrate from a first side of the substrate. The substrate is positioned in a processing volume of a processing chamber. The method includes supplying a plasma in a processing volume of a processing chamber from a second side of the substrate, and flowing one or more process gases over the substrate from the second side of the substrate. The method includes depositing one or more layers on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic side cross-sectional view of a processing chamber, according to one or more embodiments.

FIG. 2 is a schematic partial top view of the heat source module shown in FIG. 1, according to one or more embodiments.

FIG. 3 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to plasma generation and light-emitting diode (LED) configurations for processing chambers, and related apparatus and methods, for semiconductor manufacturing.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

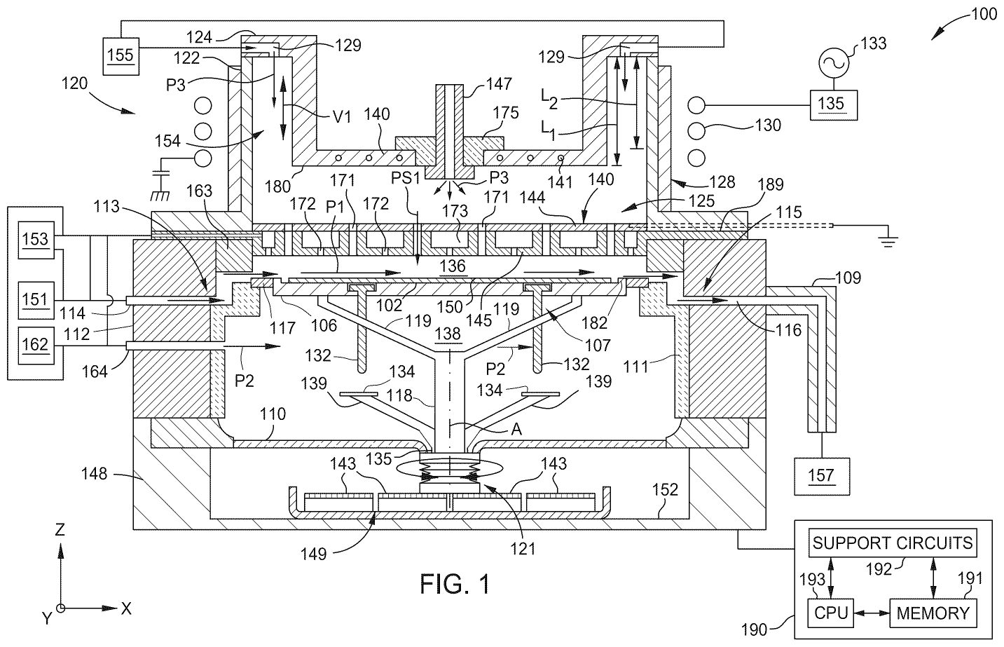

FIG. 1 is a schematic side cross-sectional view of a processing chamber 100, according to one or more embodiments. The processing chamber 100 is a deposition chamber. In one or more embodiments, the processing chamber 100 is a deposition chamber, such as an epitaxial deposition chamber. The processing chamber 100 is utilized to grow an epitaxial film on a substrate 102, and the processing chamber 100 is used to supply a plasma for plasma operations (such as plasma-assisted film deposition, ion supply into the substrate 102, pre-cleaning of the substrate 102, etching of the substrate 102, and/or cleaning of the processing chamber 100). In one or more embodiments, the processing chamber 100 creates a cross-flow of precursors across a top surface 150 of the substrate 102. The processing chamber 100 is shown in a processing condition in FIG. 1.

The processing chamber 100 includes a lower body 148 disposed below a flow module 112. Disposed within the chamber body is a substrate support 106, a lower plate 110, and one or more heat sources 143 (a plurality of heat sources 143 are shown). The plate 110 is formed at least partially of an energy transmissive material, such as transparent quartz. The plate 110 can include a window. The plate 110 can be at least partially curved, such as in the shape of a dome. The plate 110 can be at least partially flat. The processing chamber 100 includes one or more heat sources 143. The plurality of heat sources 143 are disposed between the plate 110 and a floor 152. The plurality of lower heat sources 143 form a portion of a heat source module 149. In one or more embodiments, the one or more heat sources 143 include a plurality of heat sources 143 disposed below the substrate support 106. The one or more heat sources 143 are operable to heat the processing volume 136 from one side of the substrate 102 (e.g., from below the substrate 102).

The one or more heat sources 143 include one or more diodes, such as light emitting diodes (LEDs) and/or laser diodes (e.g., vertical-cavity surface-emitting laser(s) (VCSEL(s))). At least part of the light emitted by the one or more diodes is ultraviolet light having a wavelength within a range of 30 nm to 420 nm. In one or more embodiments, the wavelength is within a range of 345 nm to 395 nm. The diodes are operable to emit radiation having a peak intensity at a target wavelength. For example, the radiation spikes at the target wavelength. The target wavelength is within a range of 330 nm to about 420 nm. In one or more embodiments, the target wavelength is within a range of 345 nm to 395 nm. The wavelength and/or target wavelength of light emitted from the one or more diodes may be changed during processing in order to affect the deposition process and/or cleaning process. For example, a first wavelength of light may be emitted from at least one of the one or more diodes to activate the process gas P1 and a second wavelength of light may be emitted during a processing chamber cleaning process. Further, the one or more diodes can facilitate more efficient metrology and pyrometry of the substrate 102 and components of the processing chamber 100 (such as the substrate support 106), in part due to the diodes emitting particular wavelengths of light, as opposed to broader ranges of wavelengths. By emitting more particular wavelengths of light, the amount of noise in the system from other wavelengths of light can be reduced, making it easier for sensors (e.g., the pyrometer(s) and/or other metrology tools) to able to more accurately measure temperature (and other properties) of the substrate 102.

The present disclosure contemplates that other heat source(s) may be used in addition to or in place of at least one of the one or more heat sources 143. The other heat source(s) can include for example lamps (such as halogen lamps or UV lamps), resistive heaters, and/or or any other suitable heat source singly or in combination.

The substrate support 106 is disposed in the processing volume 136 and between a plasma source and the plate 110. The plasma source includes a plasma source assembly 120. The substrate support 106 is disposed above the one or more heat sources 143, and the substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The processing volume 136 and a purge volume 138 are formed between the plasma source assembly 120 and the plate 110. The processing volume 136 and the purge volume 138 are part of an internal volume defined at least partially by the plasma source assembly 120, the plate 110, and one or more liners 111, 163. The one or more liners 111, 163 are disposed inwardly of the flow module 112. A chamber body can include the flow module 112, the lower body 148, and one or more liners 111, 163. The plasma source assembly 120 is disposed on a first side of the substrate support 106 and the one or more heat sources 143 are disposed on a second side of the substrate support 106.

The processing volume 136 has the substrate support 106 disposed therein. The substrate support 106 includes a top surface on which the substrate 102 is disposed. The substrate support 106 is attached to a shaft 118. In one or more embodiments, the substrate support 106 is coupled to the shaft 118 through one or more arms 119 coupled to the shaft 118. The shaft 118 is coupled to a motion assembly 121. The motion assembly 121 includes one or more actuators and/or adjustment devices that provide movement and/or adjustment for the shaft 118 and/or the substrate support 106 within the processing volume 136. The motion assembly 121 is operable to lift, lower, and/or rotate the substrate support 106. In one or more embodiments, the one or more heat sources 143 are disposed below the motion assembly 121.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 118.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 are part of an inject portion 113 of the chamber body, and the one or more gas exhaust outlets 116 are part of an exhaust portion 115 of the chamber body. The one or more gas inlets and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 can include a complete ring or one or more ring segments. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111.

During a deposition operation (e.g., an epitaxial growth operation), the one or more process gases P1 flow through the one or more gas inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

A plasma can be generated using the plasma source assembly 120 (e.g., in a plasma generation region) by a plasma generator (e.g., a radiofrequency (RF) coil 130) and desired particle flow from the plasma source assembly 120 to the substrate 102.

The plasma source assembly 120 includes a sidewall 122 and a top cover 124. The sidewall 122 and top cover 124, including an insert 140, at least partially define a plasma source volume 125. The sidewall 122 is dielectric and can include any suitable dielectric material, such as quartz, silicon carbide (SiC), and/or graphite coated with SiC. Other materials are contemplated The RF coil 130 is disposed proximate (e.g., adjacent) and about the sidewall 122 of the plasma source assembly 120. The RF coil 130 is coupled to an RF power generator 133 through a matching network 135. Feed gas(es) P3 are introduced to the plasma source volume 125 from a plasma gas supply 155. The feed gas(es) P3 can flow through one or more openings 129 formed in the top cover 124. When the RF coil 130 is energized with RF power from the RF power generator 133, a plasma is generated in the plasma source assembly 120. In one or more embodiments, the plasma is generated using the plasma source assembly 120 in an inductively coupled plasma (ICP) manner. In one or more embodiments, RF power is provided to coil 130 at about 1 kW to about 15 kW, such as about 3 kW to about 10 kW. The coil 130 may ignite and sustain a plasma in a wide pressure and flow range. In one or more embodiments, the processing chamber 100 includes a grounded Faraday shield 128 to reduce capacitive coupling of the induction coil 130 to the plasma.

To increase efficiency, the insert 140 is a gas injection insert disposed to extend into the plasma source volume 125. The gas injection insert includes one or more cooling channels 141 configured to cool the gas injection insert 140 during the processing of the substrate 102 and/or during generation of the plasma. One or more gas injection channels 154 provide the feed gas(es) P3 to the plasma source volume 125 through an active region 172, where due to enhanced confinement of hot electrons a reaction between hot electrons and the feed gas(es) P3 occurs. The reaction of can occur, for example, in the one or more gas injection channels 154 between the insert 140 and the sidewall 122 and/or the active region 172 described below. The one or more gas injection channels 154 extend annularly between the sidewall 122 and the insert 140. The feed gas(es) used to generate the plasma may include but is not limited to one or more of: hydrogen (H₂), xenon (Xe₂), fluorine (F₂), krypton fluoride (KrF), neon (Ne), bromine (Br₂), chlorine (Cl₂), iodine (I₂), and/or any mixtures thereof (such as xenon and neon). In one or more embodiments, the feed gas(es) includes one or more silicon-containing gases (e.g., silane, dichlorosilane (DCS), trichlorosilane (TCS), disilane (DS), and/or tetraclorosilane) and/or an inert gas (e.g., argon, hydrogen, nitrogen, and/or helium). In one or more embodiments, the feed gas(es) include one or more dopant gases, such as germane, diborane, and/or phosphorous. Other gases are contemplated for the feed gas(es) P3. The active region 172 (which can be an enhanced electron confinement region) is defined by sidewalls of insert 140 and the sidewall 122 in a radial direction and by the edge of a bottom surface 180 of the insert 140 from the bottom in the vertical direction. The active region 172 provides an electron confinement region within the plasma source volume 125 for efficient plasma generation and sustaining. The one or more gas injection channels 154 can be about 1 mm in width or greater, such as about 10 mm or greater, such as about 1 mm to about 10 mm. The insert 140 guides the feed gas(es) P3 to be passed through the active region 172 where plasma is formed.

In addition to or in place of the flow of the feed gas(es) P3 through the 129, the feed gas(es) P3 can be supplied through a conduit 147 and generated into the plasma PS1. The conduit 147 can be disposed through a retention flange 175 supported by the insert 140.

The capabilities of the insert 140 to improve efficiency of the processing chamber 100 can be independent of the material of the gas injection insert 140, such as when the walls that are in direct contact with radicals are made of material with a low recombination rate for the radicals. For instance, in one or more embodiments, the gas injection insert 140 can be made from a metal, such as an aluminum material or steel material, with a coating configured to reduce surface recombination. In one or more embodiments, the gas injection insert 140 can be made of a dielectric material, such as a quartz material, SiC, and/or graphite coated with SiC, or an insulative material.

The coil 130 is aligned with the active region 172 and/or the one or more gas channels 154 in such a way that the top turn of the coil 130 is above the bottom surface 180 of the insert 140 and can operate substantially in the active region 172 of the inner volume and/or the one or more gas channels 154, while the bottom turn of the coil is below the bottom surface 180. The center of the coil 130 is substantially aligned with the bottom surface 180. The position of the coil 130 can be adjusted for a desired performance. Alignment of the coil 130 with bottom surface 180 provides improved source efficiency, namely controlled generation of desired chemical species for plasma processes and delivering them to the substrate 102 with reduced or eliminated losses. For example, plasma sustaining conditions (e.g., balance between local generation and loss of ions) can be enhanced in light of generating species for a plasma process. Regarding delivery of the species to the substrate 102, efficiency can depend on the volume and wall recombination of the species. Hence, control of the alignment of the coil 130 with bottom surface 180 provides control of the source efficiency for a plasma process.

In one or more embodiments, the coil 130 has a short transition region near the leads, and the remainder of the coil turns are parallel to the bottom surface 180. In one or more embodiments, the coil 130 is helical. In one or more embodiments, the coil 130 has 2-5 turns. Other shapes and numbers of turns are contemplates for the coil 130. The coil 130 can extend below the bottom surface 180.

In one or more embodiments, the bottom surface 180 is aligned with a portion of induction coil 130 (e.g., a coil loop) by utilizing the suitably sized insert 140 (and top cover 124, of which the insert 140 may be a preformed part) to form the plasma source assembly 120. The bottom surface 180 can be movable along a vertical direction V1 relative to the plasma source assembly 120 while a remainder portion of insert 140 is static (e.g., fixed) as part of plasma source assembly 120, in order to provide alignment of bottom surface 180 with a portion of the coil 130. For example, a mechanism can be coupled with a portion of insert 140 to adjust a position of bottom surface 180 such that a portion of insert 140 having a first length (L1) is adjusted relative to a second length (L2). The mechanism can be for example an actuator, for example a motor, electric motor, stepper motor, or pneumatic actuator. Other mechanisms are contemplated. In one or more embodiments, a difference (Δ) in length from L1 to L2 is about 0.1 cm to about 4 cm, such as about 1 cm to about 2 cm.

The insert 140 can be coupled to a mechanism, and the mechanism is configured to move the entirety of insert 140 vertically (e.g., along a vertical direction V1 relative to plasma source assembly 120), in order to align bottom surface 180 with a portion of coil 130. Spacers (not shown) can be used to fill gap(s) between insert 140 and another portion of plasma source assembly 120 (such as between top cover 124 and sidewall 122) that were formed by moving the insert vertically. The spacers may be formed from, for example, a ceramic material, such as a quartz. In general, positioning a center of the coil 130 above bottom surface 180 can increase the efficiency of ionization and dissociation. Positioning the coil 130 below bottom surface 180 can improve plasma delivery efficiency.

The processing chamber 100 includes a showerhead 170 that separates the plasma source assembly 120 from the processing volume 136. The showerhead 170 includes a plurality of first openings 171 fluidly connecting the plasma source volume 125 to the processing volume 136, and a plurality of second openings 172 fluidly connecting the processing volume 136 to a channel 173 that is separated from the plasma source volume 125 by at least a section of the showerhead 170. The showerhead 170 can include one or more plates 144, 145 (two are shown in FIG. 1). The first openings 171 can be formed in a first plate 144 and a second plate 145. The second openings 172 are formed in the second plate 145. The channel 173 is defined between the first plate 144 and the second plate 145. The present disclosure contemplates that the plates 144, 145 can be integrally formed. At least one of the one or more plates 144, 145 can be conductive to filter plasma charged particles (ions and electrons), which recombine on the conductive plate(s), so that neutral plasma species can pass through the conductive plate(s) into the processing volume 136 while other species are blocked. The conductive plate(s) 144, 145 are formed of a conductive material. In one or more embodiments, the conductive material includes silicon carbide (SiC), molybdenum, tungsten, stainless steel, and/or aluminum (such as anodized aluminum). Openings 171 and/or 172 may have an average diameter of about 4 mm to about 6 mm. In one or more embodiments, the first plate 144 and/or the second plate 145 have a thickness of about 5 mm to about 10 mm, which defines the opening 188 length (L1). The conductive plate(s) can function as an ion filter (e.g., an ion blocker plate) such that, as the plasma PS1 flows past the conductive plate(s) 144, 145, radicals flow through the openings 171, 172 and past the conductive plate(s) while ions are at least partially blocked by the conductive plate(s) and conduct through the conductive plate(s) and to ground through a ground electrode 189. The ground electrode 189 extends into the conductive plate(s) 144, 145 on a side aligned with the exhaust portion 115 of the processing chamber 100.

The plasma PS1 can be supplied in the processing volume 136 during the flowing of the one or more process gases P1 (e.g., deposition gases and/or the cleaning gases) to facilitate breaking bonds, e.g., for deposition on the substrate 102 and/or cleaning. The plasma PS1 can be supplied in the processing volume 136 before the flowing of the one or more process gases P1 (e.g., to pre-clean the substrate 102), or after the flowing of the one or more process gases P1 (e.g., to etch the substrate 102, supply ions into the substrate 102, and/or to clean the processing chamber 100). The present disclosure also contemplates that the plasma PS1 can be supplied through the one or more gas inlets 114. The present disclosure further contemplates that the process gases P1 can be supplied (additionally to or in place of the process gases supplied through the gas inlets 114) to the process volume 136 through the channel 173 and the second openings 172 of the showerhead 170. The showerhead 170 facilitates accurate and adjustable process reaction and/or film growth.

Radicals (such as hydrogen radicals) of the plasma PS1 and/or the UV light from the diodes can be used to enhance gas activation (e.g., decomposition) of the process gases P1 to enhance film growth rates and growth uniformity. The radicals and the process gases P1 can mix in the processing volume 136 to facilitate gas activation and quality film growth.

As shown, a controller 190 is in communication with the processing chamber 100 and is used to control processes and methods, such as the operations of the methods described herein. The controller 190 is configured to receive data or input as sensor readings from sensor(s). The sensor devices can include, for example: sensor devices that monitor growth of layer(s) on the substrate 102; and/or sensor devices that monitor temperatures of the substrate 102, the one or more heaters, the substrate support 106, and/or the liners 111, 163. As an example, one or more sensor devices can measure temperatures and/or plasma parameters, and power to the one or more heat sources 143 and/or the RF coil 130 can be controlled based on the measurements (e.g., using a feedback control). As described the one or more sensor devices can include, for example pyrometers. In one or more embodiments, one or more thermocouples (e.g., proximity thermocouples) are disposed to measure the temperatures and power to the one or more heat sources 143 can be controlled based on the measured temperatures (e.g., using a feedback control). As an example, one or more of the sensor devices can measure one or more gas parameters and/or one or more plasma parameters (such as ion density, electron temperature, electron density, energy distribution, enthalpy, and/or absorption). In one or more embodiments, one or more of the sensor devices include a residual gas analyzer, an optical emission spectrometer, an enthalpy probe, a Langmuir probe, Faraday cup, and/or an absorption spectrometer.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power applied to the coil 130, a power applied to the heat sources 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations (such as operations of the method 300) described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to one or more heat sources 143, power to the coil 130, the deposition, the cleaning, the rotational position, the heating, and gas flow through the processing chamber 100 by providing an output to the controls for the sensor devices, the one or more heat sources 143, the RF power generator 133, the process gas source 151, the purge gas source 162, the plasma gas supply 155, the motion assembly 121, and/or the exhaust pump 157.

During processing, in one or more embodiments, the substrate 102 is heated to a target temperature of 400 degrees Celsius or higher or 600 degrees Celsius or less. In one or more embodiments, the target temperature for the substrate 102 is within a range of 380 degrees Celsius to 600 degrees Celsius, for example 400 degrees Celsius to 500 degrees Celsius. In one or more embodiments, the target temperature for the substrate 102 is less than 500degrees Celsius. In one or more embodiments, the target temperature for the substrate 102 is 400 degrees Celsius or less, such as less than 200 degrees Celsius (for example about 150 degrees Celsius.

The controller 190 is in communication, for example, with the heat sources 143 and the RF coil 130. The instructions stored in the memory 191 of the controller 190 can include one or more machine learning and/or artificial intelligence algorithms that can be executed in addition to the operations described herein. As an example, a machine learning and/or artificial intelligence algorithm executed by the controller 190 can determine one or more of: an optimal target wavelength (e.g., of the peak) for the heat sources 143, an optimal wavelength for the heat sources 143, or an optimal intensity for the heat sources 143. As another example, a machine learning and/or artificial intelligence algorithm executed by the controller 190 can determine an RF power and/or a frequency of RF current supplied to the RF coil 130.

The machine learning and/or artificial intelligence algorithm can account for previous operational runs to monitor and update measurement data used to determine the optimal parameters. The machine learning and/or artificial intelligence algorithm can select and/or adjust the deviation used to detect the profess shift in operation 310. The machine learning and/or artificial intelligence algorithm can optimize the adjusted process parameter(s) of the adjusted process recipe. The one or more machine learning and/or artificial intelligence algorithms can use, for example, a regression model (such as a linear regression model) or a clustering technique to estimate optimized parameters and/or optimized values for signal profiles and/or reference profiles. The algorithm(s) can be unsupervised or supervised. In one or more embodiments, the controller 175 automatically conducts the operations described herein without the use of one or more machine learning and/or artificial intelligence algorithms. In one or more embodiments, the controller 175 compares measurements to data in a look-up table and/or a library to determine if the shift is detected in operation 310. The controller 175 can store measurements as data in the look-up table and/or the library.

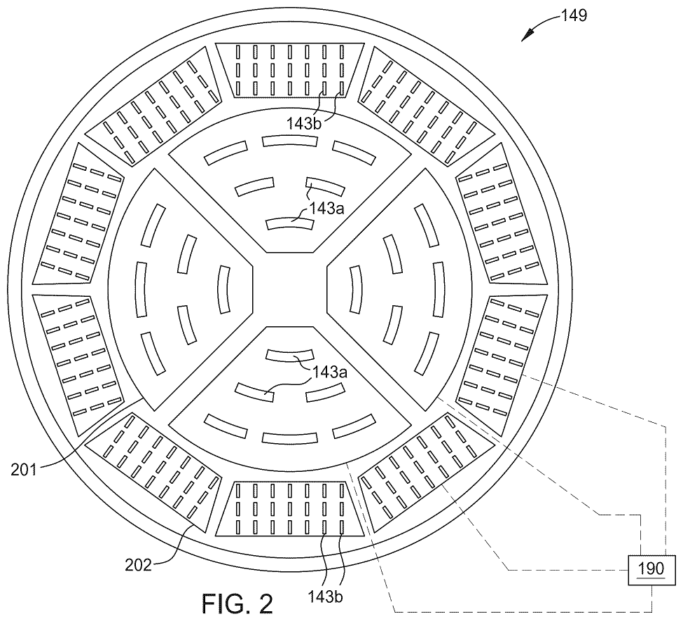

FIG. 2 is a schematic partial top view of the heat source module 149 shown in FIG. 1, according to one or more embodiments.

The one or more heat sources 143 includes a plurality of diodes disposed in a first array of diodes 143a, and a second array of diodes 143b disposed about the first array 143a. The first array of diodes 143a are disposed along sections of a circle, and the second array of diodes 143b are disposed along a circumferential pattern about the first array of diodes 143a. The diodes 143a are mounted on first plate segments 201 (four are shown in FIG. 2, other numbers are contemplated), and the diodes 143b are mounted on second plate segments 202 (ten are shown in FIG. 2, other numbers are contemplated). The respective plate segments 201, 202 can include, for example, printed circuit boards (PCBs). In one or more embodiments, the diodes 143a of the first array are independently controllable relative to the diodes 143b of the second array, such as by using the controller 190. In one or more embodiments, the controller 190 is in communication independently with the diodes 143a, 143b of each respective plate segment 201, 202 such that the diodes 143a, 143b of each respective plate segment 201, 202 can be independently controller using the controller 190. In one or more embodiments, the diodes 143a, 143b of the first array and the second array are operable to emit radiation having a peak intensity at the target wavelength described above.

The present disclosure contemplates that the first diodes 143a and/or the second diodes 143b can be arcuate and/or circumferentially oriented (as shown for the first diodes 143a in FIG. 2). The present disclosure contemplates that the first diodes 143a and/or the second diodes 143b can be linear and/or radially oriented (as shown for the second diodes 143b in FIG. 2).

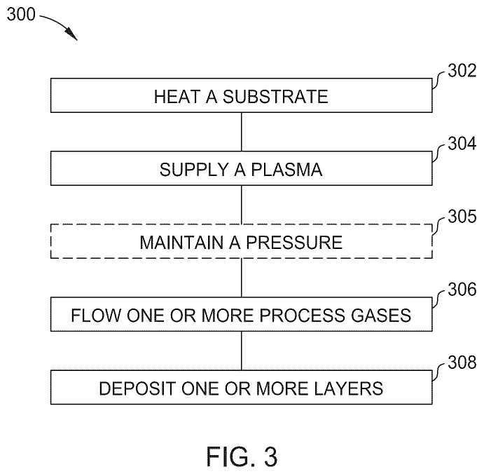

FIG. 3 is a schematic block diagram view of a method 300 of substrate processing for semiconductor manufacturing, according to one or more embodiments.

Operation 302 of the method 300 includes heating a substrate 102 positioned on the substrate support 106 of the processing chamber 100. The substrate 102 is heated from a first side of the substrate 102 (such as one side of the substrate 102). The heating of the substrate includes emitting an ultraviolet (UV) light toward the processing volume. In one or more embodiments, the UV light has a peak intensity at the target wavelength described above.

The heating includes heating the substrate 102 to a target temperature. In one or more embodiments, the target temperature for the substrate 102 is 600 degrees Celsius or less, such as less than 500 degrees Celsius. In one or more embodiments, the target temperature is 400 degrees Celsius or less, such as less than 200 degrees Celsius (for example about 150 degrees Celsius). In one or more embodiments, the target temperature for the substrate 102 is 400 degrees Celsius or higher or 600 degrees Celsius or less. In one or more embodiments, the target temperature for the substrate 102 is within a range of 380 degrees Celsius to 600 degrees Celsius, for example 400 degrees Celsius to 500 degrees Celsius. In one or more embodiments, the target temperature for the substrate 102 is about 400 degrees Celsius. The heating can be accomplished at least partially by the heat sources 143 (FIG. 1). Other temperatures are contemplated.

Operation 304 includes supplying a plasma in the processing volume 136 of the processing chamber 100 from a second side of the substrate 102. The second side of the substrate 102 opposes the first side. The plasma can be generated outside of the processing volume and then flowed into the processing volume.

Optional operation 305 includes maintaining the processing volume at a pressure. In one or more embodiments, the pressure is maintained to be less than 60 Torr, such as within a range of 0 Torr to 30 Torr. In one or more embodiments, the pressure is maintained to be less than 1 Torr, such as within a range of 0 Torr to 5 mTorr. Other pressures (such as 100 Torr or higher, for example) are contemplated.

Operation 306 includes flowing one or more process gases over the substrate 102. In one or more embodiments, the plasma of operation 304 is supplied during the flowing of the one or more process gases of operation 306, and the plasma (and/or particles thereof, such as radicals, ions, and/or neutrons) flows over the substrate 102. In one or more embodiments, the plasma (and/or particles thereof) of operation 304 is supplied before or after the flowing of the one or more process gases of operation 306. The one or more process gases can flow over the second side of the substrate 102. In one or more embodiments, the one or more process gases flow from the second side of the substrate 102.

Operation 308 includes depositing one or more layers on the substrate 102. In one or more embodiments, the plasma of operation 304 is supplied during the depositing of operation 308. In one or more embodiments, the plasma of operation 304 is supplied before or after the depositing of operation 308.

Benefits of the present disclosure include reliable gas activation (such as at relatively low processing temperatures); faster growth rates; enhanced film quality; faster substrate heating; adjustability of gas activation; modularity of using plasma operations and epitaxial deposition operations in a single chamber; modularity in chamber application; more uniform gas activation; temperature uniformity (e.g., temperature uniformity in an outer region of the substrate); reduced gas consumption and gas waste; increased growth rates; and more uniform film growth and/or dopant concentration. As an example, ions and/or radicals can be used to activate gases for processing in addition to or in place of electromagnetic radiation (such as infrared radiation and/or ultraviolet radiation).

Benefits also include enhanced device performance; reduced or eliminated occurrences of unintended dopant diffusions; efficient processing; and increased throughput. As an example, the gas activation is facilitated for a variety substrate target temperatures, including substrate target temperatures less than 500 degrees Celsius, such as target temperatures within a range of 380 degrees to 500 degrees Celsius, to facilitate reduced or eliminated interference with substrate properties. For example, gas can be activated for processing operations when the substrate is at about 400 degrees Celsius or less.

It is contemplated that one or more aspects disclosed herein may be combined. As an example, one or more aspects, features, components, operations and/or properties of the processing chamber 100, the controller 190, the heat source module 149, and/or the method 300 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for use in semiconductor manufacturing, comprising:
a chamber body at least partially defining a processing volume;
a plasma source operable to flow a plasma to the processing volume;
a substrate support disposed in the processing volume; and
one or more diodes operable to heat the processing volume.

2. The processing chamber of claim 1, wherein the plasma source includes a plasma source assembly comprising:
a sidewall operable to flow a gas toward the processing volume;
an insert disposed within the sidewall, the insert and the sidewall at least partially defining one or more gas injection channels therebetween, and the one or more gas injection channels extending annularly between the sidewall and the insert; and
a plasma generator disposed around the sidewall, the plasma generator operable to ignite the gas into the plasma.

3. The processing chamber of claim 1, further comprising a showerhead comprising:
a plurality of first openings fluidly connecting the plasma source volume to the processing volume; and
a plurality of second openings fluidly connecting the processing volume to a channel that is separated from the plasma source volume by at least a section of the showerhead.

4. The processing chamber of claim 3, wherein one or more plates of the showerhead are conductive.

5. The processing chamber of claim 1, wherein the plasma generator comprises a radiofrequency (RF) coil.

6. The processing chamber of claim 1, wherein the one or more diodes are operable to emit radiation having a peak intensity at a target wavelength, and the target wavelength is within a range of 330 nm to 420 nm.

7. The processing chamber of claim 6, wherein the target wavelength is within a range of 345 nm to 395 nm.

8. The processing chamber of claim 1, wherein the plasma source is disposed on a first side of the substrate support and the one or more diodes are disposed on a second side of the substrate support.

9. A processing chamber applicable for use in semiconductor manufacturing, comprising:
a chamber body comprising an inject section and an exhaust section, the chamber body at least partially defining a processing volume;
a substrate support disposed in the processing volume; and
one or more light-emitting diodes (LEDs) operable to emit ultraviolet (UV) light to heat the processing volume.

10. The processing chamber of claim 9, wherein the UV light has a wavelength within a range of 330 nm to 420 nm.

11. The processing chamber of claim 9, wherein the one or more LEDs are operable to emit radiation having a peak intensity at a target wavelength, and the target wavelength is within a range of 330 nm to 420 nm.

12. The processing chamber of claim 11, wherein the target wavelength is within a range of 345 nm to 395 nm.

13. The processing chamber of claim 9, wherein the one or more LEDs include a plurality of LEDs disposed in:
a first array of LEDs; and
a second array of LEDs disposed about the first array.

14. The processing chamber of claim 13, wherein the first array of LEDs are disposed along sections of a circle, and the second array of LEDs are disposed along a circumferential pattern.

15. The processing chamber of claim 13, wherein the LEDs of the first array are independently controllable relative to the LEDs of the second array.

16. The processing chamber of claim 15, wherein the LEDs of the first array and the second array are operable to emit radiation having a peak intensity at a target wavelength, and the target wavelength is within a range of 330 nm to 420 nm.

17. The processing chamber of claim 15, further comprising a controller in communication with the LEDs of the first array and the second array, the controller comprising an algorithm that when executed determines an optimal target wavelength for one or more of the LEDs.

18. A method of substrate processing, comprising:
heating a substrate from a first side of the substrate, the substrate positioned in a processing volume of a processing chamber;
supplying a plasma in a processing volume of a processing chamber from a second side of the substrate;
flowing one or more process gases over the substrate; and
depositing one or more layers on the substrate.

19. The method of claim 18, wherein the heating of the substrate comprises emitting an ultraviolet (UV) light toward the processing volume.

20. The method of claim 19, wherein the UV light has a peak intensity at a target wavelength, and the target wavelength is within a range of 330 nm to 420 nm.
